(19) United States
(12) Patent Application Publication
(10) Pub. No.: US 2025/0321276 A1
(43) Pub. Date: Oct. 16, 2025

(54) METHODS AND SYSTEMS FOR DETERMINING BATTERY STATE OF HEALTH

(71) Applicant: Comcast Cable Communications, LLC, Philadelphia, PA (US)

(72) Inventors: Michael Nispel, Downington, PA (US); Alexander Falcon, Downington, PA (US); Paul Schauer, Downington, PA (US); Jon-En Wang, Downington, PA (US)

(21) Appl. No.: 18/634,299

(22) Filed: Apr. 12, 2024

(51) Int. Cl. G01R 31/367; G01R 31/392; H02J 7/00

(52) U.S. Cl. CPC G01R 31/367; G01R 31/392; H02J 7/005

(57) ABSTRACT

Methods, apparatuses, and systems are described for determining a state of health of a battery are described. A battery may be configured to supply back-up power to a load associated with a device. The device may cause a primary power to discontinue supply power to the battery and the battery to supply power to load to cause a partial discharge of the battery based on receiving a signal to initiate a test of the battery. One or more weighted metrics of the battery may be determined based on the partial discharge of the battery. An indication of a state of health of the battery may be sent based on the one or more weighted metrics.

### BACKGROUND

Backup batteries play an essential role in the reliability of cable plant architecture. When the utility fails, batteries are relied upon to power the network and help ensure customers remain on-line. However, a battery's health will degrade due to use, environment, abuse, and many other known and unknown factors. This makes the decline in battery performance expected, but also variable and difficult to predict, with a battery's calendar age a less reliable method to determine performance. Additionally, because site loads and environmental factors play a role, every installation is unique and will cause a battery to age at a differing rate. Being able to immediately and accurately predict the battery state-of-health, such as how long a battery can provide power and its service life, is an essential operational, planning and maintenance tool. There are on-line devices that can monitor basic battery measurements, such as voltage and temperature, but these are not reliable predictors of battery runtime. For instance, discharge testing is the only accurate method accepted by the industry and battery manufacturers to determine a battery's state-of-health. There are numerous disadvantages to the existing discharge testing method. Discharge tests require removal of the battery from the system to test, require expensive load banks and other monitoring equipment, are time-consuming, and provide a value only after the testing event has completed. Moreover, conventional discharge tests require the battery to be fully discharged in order to determine the state of health of the battery.

### SUMMARY

It is to be understood that both the following general description and the following detailed description are examples and explanatory only and are not restrictive. Methods, systems, and apparatuses for determining a state of health of a battery are disclosed.

A device may receive a signal to initiate a test of a battery configured to supply back-up power to a load associated with the device. The battery may be receiving primary power from a power source to maintain a charge level of the battery prior to the signal being received by the device. Based on the signal, the battery may switch from receiving the primary power to supplying power to the load to cause a partial discharge of the battery from the first charge level to a second charge level of the battery. One or more weighted metrics of the battery may be determined during the partial discharge of the battery. A state of health of the battery may be determined and an indication of the state of health may be sent based on the one or more weighted metrics.

This summary is not intended to identify critical or essential features of the disclosure, but merely to summarize certain features and variations thereof. Other details and features will be described in the sections that follow.

### BRIEF DESCRIPTION OF THE DRAWINGS

The accompanying drawings, which are incorporated in and constitute a part of this specification, illustrate embodiments and together with the description, serve to explain the principles of the methods and systems:

FIG. 1 shows an example system for determining a state of health of a battery;

FIG. 2 shows an example graph of voltage curves associated with a plurality of batteries;

FIG. 3 shows an example graph of voltage curves associated with a plurality of batteries;

FIG. 4 shows an example graph of voltage curves associated with a plurality of batteries;

FIG. 5 shows a flowchart of an example method;

FIG. 6 shows a flowchart of an example method;

FIG. 7 shows a flowchart of an example method; and

FIG. 8 shows a block diagram of an example system and computing device.

### DETAILED DESCRIPTION

Before the present methods and systems are disclosed and described, it is to be understood that the methods and systems are not limited to specific methods, specific components, or to particular implementations. It is also to be understood that the terminology used herein is for the purpose of describing particular embodiments only and is not intended to be limiting.

As used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other components, integers or steps. “Exemplary” means “an example of” and is not intended to convey an indication of a preferred or ideal embodiment. “Such as” is not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific embodiment or combination of embodiments of the disclosed methods.

The present methods and systems may be understood more readily by reference to the following detailed description of preferred embodiments and the examples included therein and to the Figures and their previous and following description.

As will be appreciated by one skilled in the art, the methods and systems may take the form of an entirely hardware embodiment, an entirely software embodiment, or an embodiment combining software and hardware aspects. Furthermore, the methods and systems may take the form of a computer program product on a computer-readable storage medium having computer-readable program instructions (e.g., computer software) embodied in the storage medium. More particularly, the present methods and systems may take the form of web-implemented computer software. Any suitable computer-readable storage medium may be utilized including hard disks, CD-ROMs, optical storage devices, magnetic storage devices, memristor, Non-Volatile Random Access Memory (NVRAM), flash memory, or a combination thereof.

Throughout this application reference is made to block diagrams and flowcharts. It will be understood that each block of the block diagrams and flowcharts, and combinations of blocks in the block diagrams and flowcharts, respectively, may be implemented by processor-executable instructions. These processor-executable instructions may be loaded onto a general purpose computer, special purpose computer, or other programmable data processing apparatus to produce a machine, such that the processor-executable instructions which execute on the computer or other programmable data processing apparatus create a device for implementing the functions specified in the flowchart block or blocks.

These computer program instructions may also be stored in a computer-readable memory that can direct a computer or other programmable data processing apparatus to function in a particular manner, such that the instructions stored in the computer-readable memory produce an article of manufacture including computer-readable instructions for implementing the function specified in the flowchart block or blocks. The computer program instructions may also be loaded onto a computer or other programmable data processing apparatus to cause a series of operational steps to be performed on the computer or other programmable apparatus to produce a computer-implemented process such that the instructions that execute on the computer or other programmable apparatus provide steps for implementing the functions specified in the flowchart block or blocks.

Accordingly, blocks of the block diagrams and flowchart illustrations support combinations of means for performing the specified functions, combinations of steps for performing the specified functions and program instruction means for performing the specified functions. It will also be understood that each block of the block diagrams and flowchart illustrations, and combinations of blocks in the block diagrams and flowchart illustrations, can be implemented by special purpose hardware-based computer systems that perform the specified functions or steps, or combinations of special purpose hardware and computer instructions.

This detailed description may refer to a given entity performing some action. It should be understood that this language may in some cases mean that a system (e.g., a computer) owned and/or controlled by the given entity is actually performing the action.

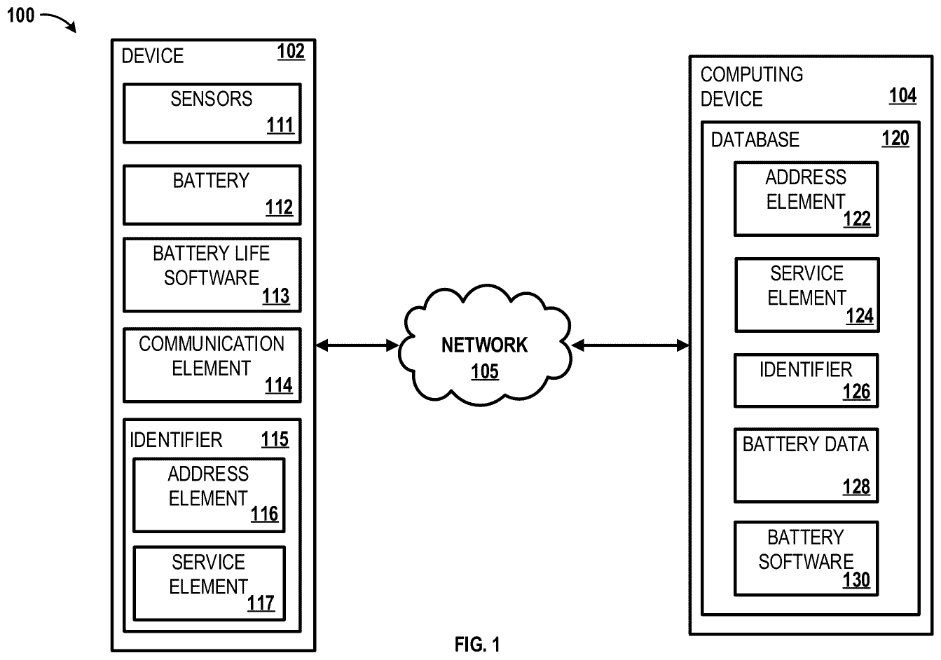

FIG. 1 shows an example system 100 for determining a state of health of a battery. For example, the system 100 may be configured to determine a state of health of a battery based on a partial discharge of the battery. The network and system 100 may be configured to provide services, such as network-related services, to a device (e.g., one or more devices 102). The system 100 may comprise one or more devices 102 associated with, or comprising, a battery 112 and a computing device 104. The computing device 104 may be disposed locally or remotely relative to the devices 102. The devices 102 and the computing device 104 may be in communication via a private and/or public network 105 such as the Internet or a local area network (LAN). The devices 102 may be in communication with a computing device 104 such as a centralized device or a server, for example. Other forms of communications can be used such as wired and wireless telecommunication channels.

The devices 102 may comprise electronic devices such as a computer, a smartphone, a laptop, a tablet, a set top box, a display device, a printer, a telephone, a cordless phone, a network node, a network device, a communication terminal, a transmitter, or other device capable of connecting to the network 105. The devices 102 may comprise sensors 111, a battery 112, battery life software 113, a communication element 114, and an identifier 115. As an example, the battery 112 may be configured to supply back-up power to a load associated with the device 102 and/or to the device 102 itself. For example, the battery 112 may be included in the device 102 to provide back-up power in the event of a power loss. In an example, the battery 112 may be provided as a backup power for cable equipment (e.g., load) located at a utility site for providing cable services to one or more users, wherein the device 102 may further comprise a capable equipment device for controlling the equipment at the utility site.

The sensors 111 may comprise a temperature sensor, a current sensor, a voltage sensor, a resistance sensor, and so forth. The sensors 111 may be used to determine (e.g., measure) the one or more metrics associated with the battery 112. For example, the sensors 112 may be configured to measure a voltage of the battery 112, a resistance of the battery 112, a current associated with the battery 112, and/or a temperature of the battery 112. The sensors 111 may be configured to determine data associated with an environment around the battery 112 and/or the device 102. For example, the sensors 111 may be configured to measure a temperature of the environment around the battery 112 and/or the device 102, determine a presence of smoke (e.g., a smoke detector) or another chemical (e.g., natural gas, carbon monoxide, etc.).

The sensors 111 may be configured to detect and/or capture information around the battery 112 and/or the device 102. For example, the sensors 111 may further comprise a camera that is configured to capture still images and/or video around the battery 112 and/or the device 102. As an example, the device 102 may comprise a security camera associated with a security system of a premises. As an example, the device 102 may comprise a security device (e.g., a glass break detector, a door open detector, etc.) associated with a security system, and the sensors 111 may capture data that indicates whether a security event (e.g., a security breach, a break-in, etc.) is occurring. For example, the sensors 111 may comprise a sound sensor (e.g., a microphone) that captures sound around the device 102.

The battery 112 may comprise any type of battery. For example, the battery 112 may comprise a rechargeable battery. The battery 112 may comprise any size, model, and/or type of battery. For example, the battery 112 may comprise a cylindrical battery (e.g., AAA, C, D, CR2, 2CR5, etc.), a rectangular battery (9 volt, 12 volt, etc.), a button cell battery (e.g., CR927, CR1220, CR2025, etc.), a zinc air cell battery (e.g., AC10, ZA13, A312, etc.), and so forth. The battery 112 may be made of any material such as alkaline, carbon zinc, Lithium-ion (Li-ion), Nickel Cadmium (Ni—Cd), Nickel-Metal Hydride (Ni-MH), Lithium-Manganese Dioxide (LiMnO₂), or any suitable battery. In an example, the battery 112 may comprise a plurality of batteries. For example, the plurality of batteries may be configured in one or more strings of the same batteries in series, parallel, or both series and parallel.

The battery 112 may have a storage capacity, which is the total amount of power (e.g., charge) that the battery 112 can store. The storage capacity of the battery 112 may or may not change over time. For example, if the battery 112 is a non-rechargeable battery, the storage capacity may not change over time because the capacity is a fixed amount since the battery 112 is not capable of being recharged. If the battery 112 is a rechargeable battery, the storage capacity of the battery may change over time as the battery 112 is used. For example, as the battery 112 is used (e.g., power is discharged from the battery 112, the battery 112 is charged, etc.), the capacity of the battery 112 may decrease due to the use. Thus, the capacity of the battery 112 may change over time, which may impact determining the amount of power remaining in the battery 112. Thus, the capacity of the battery 112 may be determined based on one or more metrics of the battery 112 and/or use of the battery 112 to account for any change in the capacity of the battery 112. Accordingly, the device 102 may be configured to take into account the change in the capacity of the battery 112 when determining a remaining power left in the battery 112.

The battery 112 may have a battery life (e.g., state of health) associated with the battery 112. For example, the battery 112 may be a rechargeable battery that has a number of usage cycles (e.g., charged and discharged) that the battery 112 can have before the battery is no longer effective (e.g., does not hold a sufficient charge for the device's 102 intended use of the battery 112, such as supplying backup power to the device 102 and/or the load associated with the device 102). As an example, the battery 112 may have a battery life of 10 usage cycles such that the battery 112 may be discharged and charged a total of 10 times before the battery 112 no longer holds a sufficient charge when fully charged due to a diminished capacity of the battery 112. The battery life (e.g., state of health) of the battery 112 may be indicated by a capacity of the battery 112. For example, when the capacity of the rechargeable battery is diminished (e.g., reduced) to the point of no longer being effective for its intended use, the life (e.g., state of health) of the battery 112 may be considered ended even though the battery 112 is still usable because the battery 112 still holds a charge. Thus, when the battery life (e.g., state of health) satisfies a threshold (e.g., when the capacity is reduced to the point that the threshold is satisfied), a notification may be generated and/or sent to indicate that the battery life (e.g., state of health) of the battery 112 is near the end of the effective life of the battery 112, and the battery 112 needs to be replaced. As an example, when the capacity of the battery 112 is reduced to a percentage (e.g., 50%, 60%, 70%, etc.) as compared to the capacity of the battery 112 when new (e.g., 100%), the notification may be generated and/or sent to indicate the that the battery 112 needs to be replaced.

The devices 102 may implement the battery life software 113 to determine a state of health (e.g., battery life) of the batteries 112 of the devices 102. The battery life software 113 may be software, firmware, and/or hardware. For example, a device 102 may receive a signal to initiate a test of its battery 112. The battery 112 may be receiving primary power (e.g., charging power) from a power source to maintain a first charge level (e.g., 100% battery capacity) of the battery 112. For example, the primary power may comprise a charging power received from the power source that charges the battery to maintain the first charge level. Based on the signal, the device 102 may implement the battery life software 113 to cause the primary power (e.g., power source providing the charging power) to discontinue supplying power to the battery 112 and the battery 112 to supply power to the load to cause a partial discharge of the battery 112 from the first charge level to a second charge level (e.g., percentage of the first charge level, or battery capacity, such as 90%, 80%, 70%, etc.) of the battery 112. For example, the device 102 may cause the battery 112 to discharge for a time period (e.g., 30 minutes, 1 hour, 3 hours, etc.) or to discharge an amount of electric charge (e.g., 10 Ah, 20 Ah, 50 Ah, etc.) from the battery 112. After the partial discharge, the device 102 may cause the battery 112 to discontinue discharging by causing the battery 112 to discontinue supplying power to the load and the primary power (e.g., from the power source) to resume supplying power to the battery 112. The device 102 may determine one or more weighted metrics of the battery 112 during the partial discharge of the battery 112. The one or more weighted metrics may comprise one or more of a voltage, a first derivative of the voltage, a second derivative of the voltage, a change in voltage from optimal, a change in voltage due to the discharge of the battery 112, a recovery of the voltage during the discharge of the battery 112, or a first and second derivate of the recovery voltage. For example, the device 102 may determine one or more metrics of the battery 112 during the partial discharge. The device 102 may assign a weight to each metric of the one or more metrics. In an example, the device 102 may determine the one or more weighted metrics from a plurality of metrics based on one or more characteristics of the battery 112. The one or more characteristics may comprise one or more of a battery model of the battery 112 or a battery type of the battery 112. For example, depending on a battery model and/or battery type of the battery 112, the device 102 may determine, or prioritize, which metrics to use for determining the state of health of the battery 112 (e.g., which metrics are more reliable for a particular battery model and/or battery type). The device 102 may determine one or more combinations of the one or more metrics, for example. In an example, the device 102 may assign the weights to the metrics based on the one or more characteristics. For example, depending on a battery model and/or battery type of the battery 112, the device 102 may assign specific weights to specific metrics, wherein certain metrics may be given more weight depending on the battery model and/or the battery type. In an example, the device 102 may assign the weights to the metrics based on applying a machine learning model to the one or more metrics. A state of health of the battery 112 may be determined based on the one or more weighted metrics. The device 102 may send an indication of the state of health to the computing device 104, for example. The state of health of the battery 112 may comprise one or more of a percentage of an original capacity of the battery or a remaining life of the battery.

The device 102 may determine the one or more weighted metrics (or metrics) at one or more depth of discharge (DOD) levels during the partial discharge of the battery 112. In an example, an initial voltage drop may be determined at a DOD level of a value of 0.5% to 3%. This metric may be used to indicate a state-of-charge, electrolyte strength, and plate health (e.g., primarily the negative plate of the battery 112). In an example, a first derivative of the initial voltage drop may be determined at a DOD level of 0.1% to 2%. This metric may be used to indicate the degradation of the health of the plate core, primarily the negative plate and primarily due to cycling. In an example, a second derivate of the initial voltage drop may be determined at a DOD level of 0.1% to 2%. This metric may be used to indicate the recovery from the initial voltage drop which may be indicative of the electrolyte strength and plate core health of the positive plate. In an example, voltage recovery from the initial voltage drop may be determined at a DOD level of 4% to 8%. This metric may be indicative of the positive plate health, both of the plate core and the positive active material health (e.g., amount and crystal size of the positive active material). In addition, this value may also be indicative of a portion of the positive grid corrosion level, which indicates a degradation of the calendar life or the design life of the battery. In an example, voltage decay from an initial plateau may be determined at a DOD level of 10% to 25%. The metric may be indicative of the health of the active material layer of the positive plate. In an example, a first derivative of the voltage decay after the initial plateau may be determined at a DOD level of 4% to 10%. This metric may be indicative of the health, primarily the crystal size of the active material of the positive plate. In an example, a first derivate decay beyond 10% DOD may be determined at a DOD level of 10% to 25%. This metric may be indicative of the plate core health of the positive plate, and a measure of the degree of cycle life that has been depleted. In an example, a second derivative voltage beyond 10% DOD may be determined at a DOD level of 10% to 25%. This metric may be indicative of the plate health of both positive and negative plates. This metric is primarily indicative of degradation from cycling, and also is a secondary indication of positive grid corrosion and loss of calendar life. In an example, a change in initial plateau voltage from optimal may be determined at a DOD level of 4% to 8%. This metric may be indicative of the change from an optimal sample set. This metric may be primarily indicative of positive grid corrosion, in addition to positive and negative plate core health. In an example, a change in voltage from optimal at DOD beyond 10% may be determined at a DOD level of 10% to 25%. In addition to positive grid corrosion, this metric may also be indicative of negative plate sulfation with a minor indication of electrolyte purity. In an example, a recovery voltage after the partial discharge of the battery 112 may be determined at various DOD levels, such as 1% to 10%. This value may be indicative of numerous mechanisms, including negative plate active material health, negative plate core health, electrolyte stratification and strength, and positive active material health. In an example, first and second derivatives of recovery voltage may be determined at various DOD levels, such as 1% to 10%. This value may be indicative of the positive plate core health and the negative plate core health.

The communication element 114 may comprise a wireless transceiver configured to transmit and receive wireless communications via a wireless communication network. The communication element 114 may be configured to communicate via a specific network protocol. The communication element 114 may comprise a wireless transceiver configured to communicate via a Wi-Fi network. The device 102 may communicate with the computing device 104, and/or a user device via the communication element 114.

The devices 102 may be associated with user identifiers or device identifiers 115. As an example, the device identifiers 115 may be any identifier, token, character, string, or the like, for differentiating one user or user device (e.g., a device 102) from another user or user device. The device identifier 115 may identify a user or user device as belonging to a particular class of users or user devices. As an example, the device identifier 115 may comprise information relating to the user device such as a manufacturer, a model or type of device, a service provider associated with the device 102, a state of the device 102, a locator, and/or a label or classifier. Other information can be represented by the device identifiers 115.

The device identifiers 115 may comprise address elements 116 and service elements 117. The address elements 116 may comprise or make available an internet protocol address, a network address, a media access control (MAC) address, an Internet address, or the like. As an example, the address elements 116 may be relied upon to establish a communication session between the devices 102 and the computing device 104 or other devices and/or networks. As an example, the address elements 116 may be used as an identifier or locator of the user devices 102. The address elements 116 may be persistent for a particular network.

The service elements 117 may comprise identification of the service providers associated with the devices 102 and/or with the class of devices 102. The class of the devices 102 may be related to a type of device, a capability of a device, a type of service being offered, and/or a level of service (e.g., a business class, a service tier, a service package, etc.). As an example, the service elements 117 may comprise information relating to or made available by a communication service provider (e.g., an Internet service provider) that is offering or enabling data flow such as communication services to the devices 102. As an example, the service elements 117 may comprise information relating to a preferred service provider for one or more particular services relating to the devices 102. The address elements 116 may be used to identify or retrieve data from the service elements 117, or vice-versa. As an example, one or more of the address elements 116 and the service elements 117 can be stored remotely from the devices 102 and retrieved by one or more devices such as the devices 102 and the computing device 104. Other information can be represented by the service element 117.

The computing device 104 may be a server, or a centralized device, for communicating with the devices 102 for sending the signal to initiate the test of the battery 112 in order to determine the state of health of the battery 112. In an example, the computing device 104 may communicate with the devices 102 for offering data and/or services. For example, the computing device 104 may offer services such as network (e.g., Internet) connectivity, network printing, media management (e.g., a media server), interference management, content services, streaming services, broadband services, or other network-related services.

The computing device 104 may allow the devices 102 to interact with remote resources such as data, devices, and files. As an example, the computing device 104 may be configured as (or disposed at) a central location (e.g., a headend, or a processing facility), which can receive content (e.g., data, input programming) from multiple sources. The computing device 104 may be a separate/remote device from the headend, for example. The computing device 104 can combine content from the multiple sources and may distribute the content to user (e.g., subscriber) locations via a distribution system.

The computing device 104 may be configured to manage the communication between the devices 102 and a storage system (e.g., a database 120) for sending and receiving data therebetween. As an example, the database 120 may store a plurality of files, user identifiers or records, or other information. As an example, the devices 102 may request and/or retrieve one or more files from the database 120. The database 120 may store information relating to the devices 102 such as the address elements 116 and/or the service elements 117. As an example, the computing device 104 may obtain the device identifiers 115 from the devices 102 and retrieve information from the database 120 such as the address elements 116 and/or the service elements 117. As an example, the computing device 104 may obtain the address elements 116 from the devices 102 and may retrieve the service elements 117 from the database 120, or vice versa. Any information can be stored in and retrieved from the database 120. The database 120 can be disposed remotely from the computing device 104 and accessed via direct or indirect connection. The database 120 can be integrated with the computing device 104 or some other device or system.

The computing device 104 may have an address element 122 and a service element 124, which may be stored in the database 122. The address element 122 may comprise or provide an internet protocol address, a network address, a media access control (MAC) address, an Internet address, or the like. The address element 122 may be relied upon to establish a communication session between the computing device 104 and the device 102 or other devices and/or networks. The address element 122 may be used as an identifier or locator of the computing device 104. The address element 122 may be persistent for a particular network.

The service element 124 may comprise an identification of a service provider associated with the computing device 104 and/or with the class of computing device 104. The class of the computing device 104 may be related to a type of device, capability of device, type of service being provided, and/or a level of service (e.g., business class, service tier, service package, etc.). The service element 124 may comprise information relating to or provided by a communication service provider (e.g., Internet service provider) that is providing or enabling data flow such as communication services to the computing device 104. The service element 124 may comprise information relating to a preferred service provider for one or more particular services relating to the computing device 104. Other information may be represented by the service element 124.

The computing device 104 may have an identifier 126, which may be stored in the database 122. The identifier 126 may be or relate to an Internet Protocol (IP) Address, a Media Access Control (MAC) address, or the like. The identifier 126 may be a unique identifier for facilitating wired and/or wireless communications with the device 102. The identifier 126 may be associated with a physical location of the computing device 104.

The database may further include battery data 128 and battery software 130. The battery data 128 may contain data related to one or more batteries (e.g., the battery 112), as well as data related to the power usage of one or more devices (e.g., the devices 102) or one or more loads. The battery data 128 may include the state of health data determined by the devices' 102 batteries 112. The computing device 104 may implement the battery software 130 to send the signal to the devices 102 to initiate the tests of the batteries 112 of the devices 102. The batteries 112 may be receiving charging power (e.g., primary power from a power source) to maintain a charge level (e.g., 100% battery capacity) of the batteries 112. The signal may cause the charging power to discontinue supplying power to the batteries 112 and the batteries 112 to supply power to the loads associated with the devices 102 to cause a partial discharge of the batteries. The computing device 104 may receive indications (e.g., data indicative) of a state of health of the batteries 112. The computing device 104 may send indications to replace one or more batteries 112 of one or more of the devices 102 based on one or more of the states of health satisfying a threshold. For example, one or more states of health may indicate that the current capacities of one or more of the batteries 112 may be below a threshold percentage of an original capacity of the battery or one or more states of health may indicate that the remaining life of the battery is below a threshold duration (e.g., minutes, hours, days, months, years, number of cycles, etc.). The computing device 104 may send the indications to replace the one or more batteries 112 based on one or more of the current capacities being below the threshold percentage or one or more of the batteries have a remaining life below the threshold duration. In an example, the battery data 128 may facilitate determining the state of health of the battery. For example, the computing device 104 may implement the battery software 130 to determine the state of health of the batteries 112 based on the battery data 128. For example, the battery data 128 may include the one or more metrics of the batteries that may be used by the computing device 104 to determine the state of health of the batteries 112.

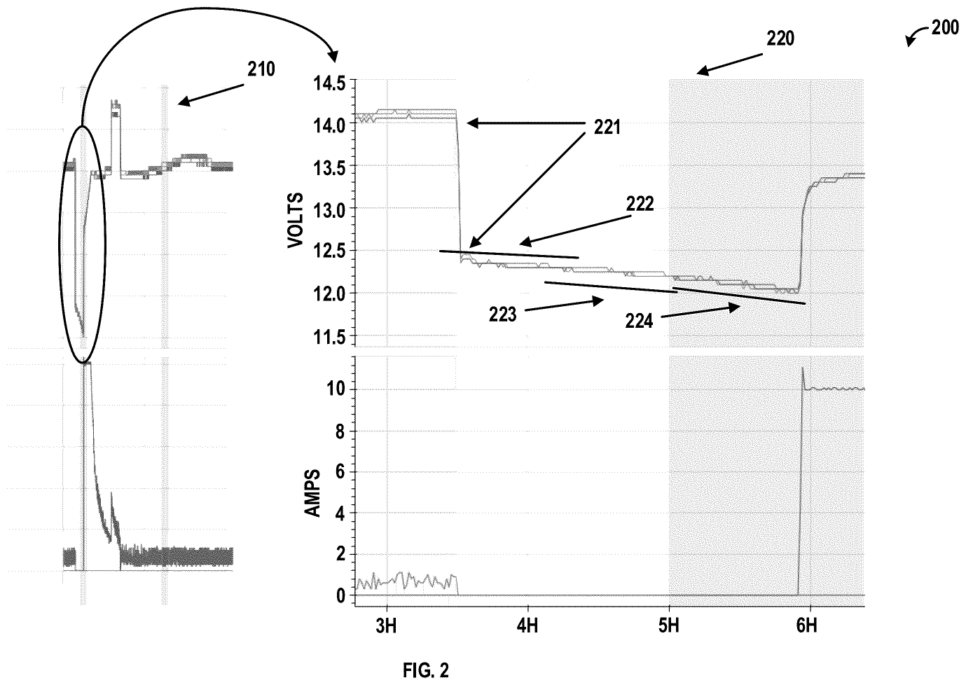

FIG. 2 shows an example graph 200 of voltage curves associated with a plurality of batteries. Graph 200 comprises metrics associated with a testing process of the plurality of batteries. For example, the batteries may be partially discharged in order to measure a voltage of the batteries over a time period (e.g., number of hours). 210 and 220 show graphs related to an initial voltage drop as the batteries are discharged during the testing process. 220 provides a more in-depth look at the initial voltage drops of the batteries by showing the slope of the voltage drops over time. 221 shows the initial voltage drop when the testing process is initiated and the batteries begin to discharge. For example, when a discharge event starts, the initial voltage drop is significant. The starting point is determined by a float voltage. The ending point is one indication of how healthy the battery is. The battery health can be derived from the combination of internal ohmic resistance (which may vary based on battery design and temperature) and electrochemical resistance (which may vary based on battery design and temperature). The smaller the drop for a level of current, the more likely the battery may be considered a healthy battery. For example, new/healthy batteries may experience some voltage drop based on battery design and battery construction. Voltage drops greater than the voltage drop of 221, as shown in FIG. 2, may indicate uncharged plates of the battery, aged plates of the battery, or a mechanical defect of the battery.

As shown in FIG. 2, after the initial voltage drop, the slope of the voltage throughout the discharge may be analyzed to determine/measure the one or more metrics. As an example, the voltage curves of the batteries shown in FIG. 2 indicate that the batteries have healthy discharge profiles since the slopes are small and consistent throughout. As shown in FIG. 2, the voltage may hit an initial minimum, and then recover, based on the initial voltage drop. For example, the recovery may be over a duration that may include a second or up to a few minutes depending on the battery design and the discharge rate. 222 shows the initial slope after the initial voltage drop. The initial slope should remain relatively unchanged as the battery ages. Deviations may indicate mechanical defects, premature aging, or severe aging. 223 and 224 show the change in slope (e.g., indicative of the second derivative of the voltage curve). The change in slope for a new battery will vary with current. The higher the discharge current, the more rapid the increase in slope. New batteries may have a metric change. This change can be used with the initial voltage drop to determine or predict the runtime. As the battery ages, the change in slope may increase. A very sharp change in the slope may indicate the onset of the knee of the curve indicating depletion of the available capacity of the battery. For example, batteries may fail quickly after the knee if reached.

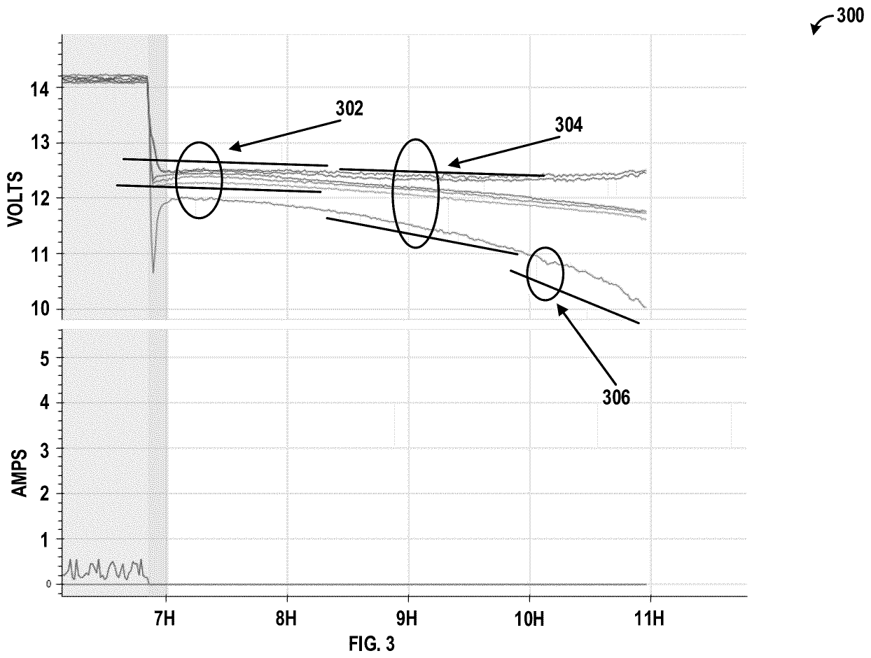

FIG. 3 shows an example graph 300 of voltage curves associated with a plurality of batteries. As shown in FIG. 3, a strong battery's voltage curve may be compared to a weak battery's voltage curve. For example, the weak battery may have a larger voltage drop than the strong battery. 302 and 304 show that the initial slope of the batteries' voltage curves begin to differentiate the weak battery from the healthy batteries. For example, 306 shows the knee of the curve of the weak battery. The graph 300 of FIG. 3 shows that the end of life of the weak battery may be determined based on an analysis of one or more aspects/characteristics of the battery's voltage curve.

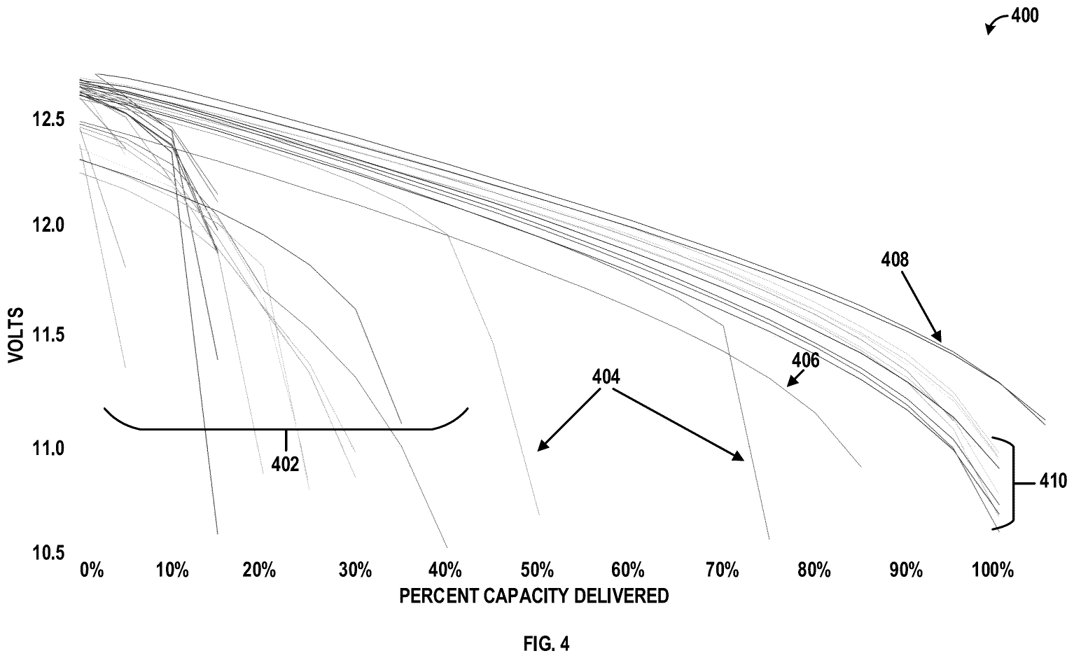

FIG. 4 shows an example graph 400 of voltage curves associated with a plurality of batteries. The graph 400 is associated with a dynamic deep cycle testing of a plurality of batteries, wherein the batteries are partially discharged. For example, the batteries are discharged for a predetermined time period (e.g., minutes, hours, etc.) or the batteries are discharged a predetermined capacity amount (e.g., 10 Ah, 20 Ah, 25 Ah, etc.). This predetermined discharge amount thus allows each voltage curve to then be directly compared to an expected curve (e.g., of a healthy/strong battery). Based on the one or more metrics determined from the voltage curves, battery health may be determined and the batteries may be sorted/ranked based on the batteries' performances. As an example, an initial voltage drop and initial slope of the voltage decay may be compared to determine a figure-of-merit (FOM) for the battery's state of health. For example, 402 shows the voltage curves of weak batteries suffering from premature aging (e.g., overcycling, mechanical failure, etc.). 404 shows the voltage curves of batteries suffering from acid dryout. 406 shows the voltage curve of a battery that aged normally. 408 shows the voltage curves of new batteries. 410 shows the voltage curves of slightly aged, but still good/health batteries.

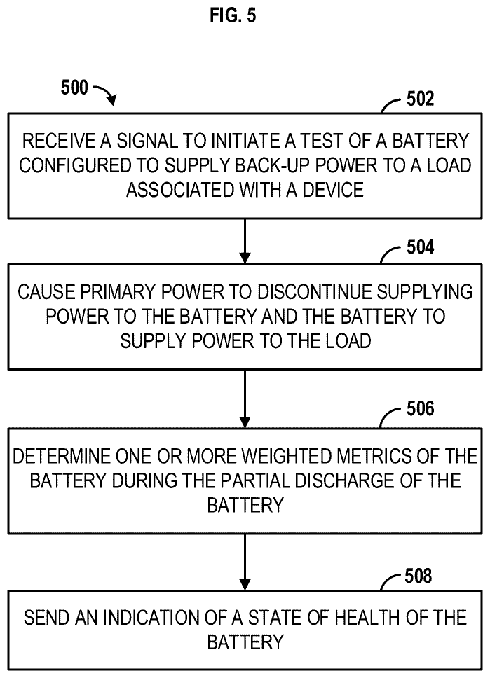

FIG. 5 shows a flowchart of an example method 500 for determining a state of health of a battery. For example, the battery may be configured to provide backup power to a load associated with a device. Method 500 may be implemented, for example, by a device (e.g., device 102). At step 502, a signal to initiate a test of a battery configured to supply back-up power to a load associated with a device may be received. For example, a device (e.g., device 102) may receive the signal to initiate the test of the battery configured to supply back-up power to the load associated with the device. The battery may be receiving primary power to maintain a first charge level (e.g., 100% battery capacity) of the battery prior to the device receiving the signal. For example, the battery may be receiving the primary power from a power source prior to the device receiving the signal. For example, the primary power may comprise a charging power received from the power source that charges the battery to maintain the first charge level.

At step 504, based on the signal, the primary power may be caused to discontinue supplying power to the battery and the battery may be caused to supply power to the load to cause a partial discharge of the battery from the first charge level to a second charge level of the battery. For example, based on the signal, the device (e.g., device 102) may cause the primary power to discontinue supplying power to the battery and the battery to supply power to the load to cause the partial discharge of the battery from the first charge level to the second charge level of the battery. The second charge level may comprise a percentage (e.g., percentage of the first charge level, or battery capacity, such as 90%, 80%, 70%, etc.) of the first charge level. In an example, the battery may be caused to discharge for a time period (e.g., 30 minutes, 1 hour, 3 hours, etc.) or the battery may be caused to discharge an amount of electric charge (e.g., 10 Ah, 20 Ah, 50 Ah, etc.) from the battery. In an example, based on the discharge of the battery from the first charge level to the second charge level, the battery may be caused to discontinue supplying power to the load and the primary power (e.g., from the power source) may be caused to resume supplying power to the battery.

At step 506, one or more weighted metrics of the battery during the partial discharge of the battery may be determined. For example, the device (e.g., device 102) may determine the one or more weighted metrics of the battery during the partial discharge of the battery. In an example, one or more metrics of the battery during the partial discharge of the battery may be determined. A weight may be assigned to each metric of the one or more metrics. In an example, a weight may be assigned to each of the one or more metrics based on an application of a machine learning model to the one or more metrics. In an example, the one or more weighted metrics, or the one or more metrics, may be determined at one or more depth of discharge levels during the partial discharge of the battery. In an example, the one or more weighted metrics, or the one or more metrics, may be determined from a plurality of weighted metrics, or a plurality of metrics, based on one or more characteristics of the battery. For example, depending on a battery model and/or battery type of the battery, the device may determine, or prioritize, which metrics to use for determining the state of health of the battery (e.g., which metrics are more reliable for a particular battery model and/or battery type). The device may determine one or more combinations of the one or more metrics, for example. The one or more characteristics may comprise one or more of a battery model of the battery or a battery type of the battery. The plurality of weighted metrics, or the plurality of metrics, may comprise one or more of a voltage, a first derivative of the voltage, a second derivative of the voltage, a change in voltage from optimal, a change in voltage due to the discharge of the battery, a recovery of the voltage during the discharge of the battery, a first and second derivate of the recovery voltage.

At step 508, an indication of a state of health of the battery may be sent based on the one or more weighted metrics. For example, the device (e.g., device 102) may send the indication of the state of health of the battery based on the one or more weighted metrics. The state of health may comprise one or more of a percentage of an original capacity of the battery or a remaining life of the battery.

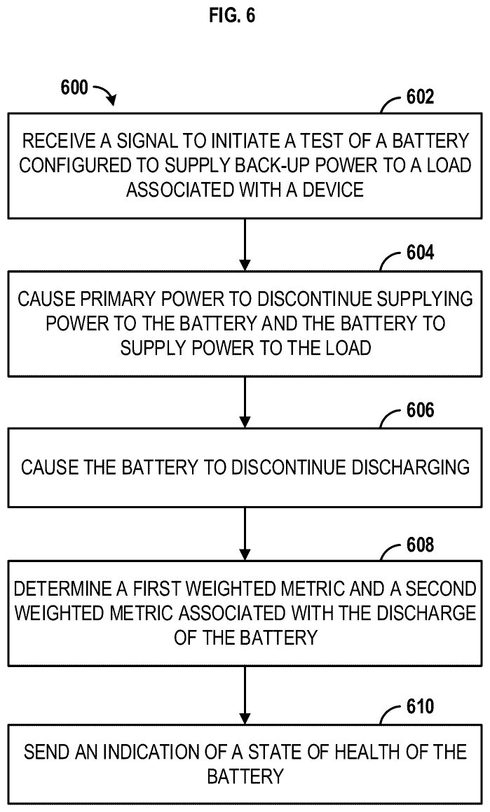

FIG. 6 shows a flowchart of an example method 600 for determining a state of health of a battery. For example, the battery may be configured to provide backup power to a load associated with a device. Method 600 may be implemented, for example, by a device (e.g., device 102). At step 602, a signal to initiate a test of a battery configured to supply back-up power to a load associated with a device may be received. For example, a device (e.g., device 102) may receive the signal to initiate the test of the battery configured to supply back-up power to the load associated with the device. The battery may be receiving primary power to maintain a charge level (e.g., 100% of the battery capacity) of the battery prior to the device receiving the signal. For example, the battery may be receiving the primary power from a power source prior to the device receiving the signal. For example, the primary power may comprise a charging power received from the power source that charges the battery to maintain the charge level.

At step 604, based on the signal, the primary power may be caused to discontinue supplying power to the battery and the battery may be caused to supply power to the load to cause a discharge of the battery to a threshold percentage of the charge level of the battery. For example, based on the signal, the device (e.g., device 102) may cause the primary power to discontinue supplying power to the battery and the battery to supply power to the load to cause the discharge of the battery to the threshold percentage of the charge level of the battery (e.g., percentage of the charge level, or the battery capacity, such as 90%, 80%, 70%, etc.). In an example, the battery may be caused to discharge for a time period (e.g., 30 minutes, 1 hour, 3 hours, etc.) or the battery may be caused to discharge an amount of electric charge (e.g., 10 Ah, 20 Ah, 50 Ah, etc.) from the battery.

At step 606, the battery may be caused to discontinue discharging based on the discharge of the battery to the threshold percentage. For example, the device (e.g., device 102) may cause the battery to discontinue discharging based on the discharge of the battery to the threshold percentage. In an example, based on the discharge of the battery to the threshold percentage of the charge level of the battery, the battery may be caused to discontinue supplying power to the load and the primary power (e.g., from the power source) may be caused to resume supplying power to the battery.

At step 608, a first weighted metric and a second weighted metric associated with the discharge of the battery may be determined. For example, the device (e.g., device 102) may determine the first weighted metric and the second weighted metric associated with the discharge of the battery. One or more of the first weighted metric or the second weighted metric may comprise one or more of a voltage, a first derivative of the voltage, a second derivative of the voltage, a change in voltage from optimal, a change in voltage due to the discharge of the battery, a recovery of the voltage during the discharge of the battery, a first and second derivate of the recovery voltage. In an example, a first metric and a second metric associated with the discharge of the battery may be determined. A first weight may be assigned to the first metric and a second weight may be assigned to the second metric. In an example, the first weight may be assigned to the first metric and the second weight may be assigned to the second metric based on one or more characteristics of the battery. For example, depending on a battery model and/or battery type of the battery, the device may assign specific weights to specific metrics, wherein certain metrics may be given more weight depending on the battery model and/or battery type. The one or more characteristics of the battery comprises one or more of a battery model of the battery or a battery type of the battery. In an example, the first weight may be assigned to the first metric and the second weight may be assigned to the second metric based on an application of a machine learning model to the first metric and the second metric.

At step 610, an indication of a state of health of the battery may be sent based on a comparison of the first weighted metric and the second weighted metric. For example, the device (e.g., device 102) may send the indication of the state of health of the battery based on the comparison of the first weighted metric and the second weighted metric. The state of health may comprise one or more of a percentage of an original capacity of the battery or a remaining life of the battery.

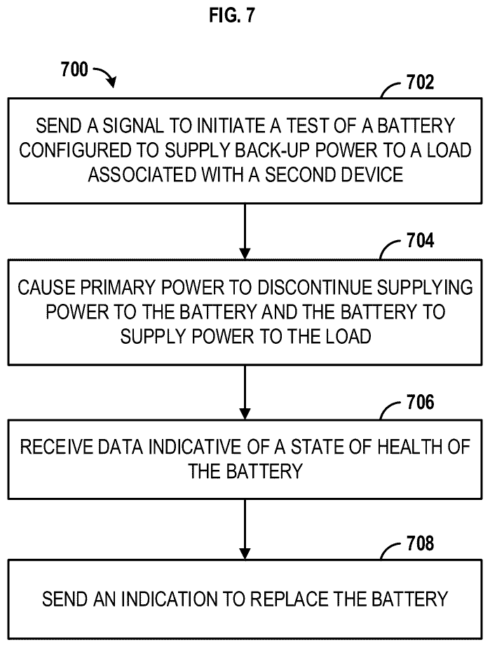

FIG. 7 shows a flowchart of an example method 700 for determining a state of health of a battery. For example, the battery may be configured to provide backup power to a load associated with a device. Method 700 may be implemented, for example, by a computing device (e.g., computing device 104). At step 702, a signal to initiate a test of a battery configured to supply back-up power to a load associated with the second device may be sent by a first device (e.g., computing device 104) to a second device (e.g., device 102). The battery may be receiving primary power to maintain a charge level (e.g., 100% battery capacity) of the battery prior to the device receiving the signal. For example, the battery may be receiving the primary power from a power source prior to the device receiving the signal. For example, the primary power may comprise a charging power received from the power source that charges the battery to maintain the charge level.

At step 704, the primary power may be caused to discontinue supplying power to the battery and the battery may be caused to supply power to the load to cause a partial discharge of the battery based on the signal. For example, the first device (e.g., computing device 104) may cause the primary power to discontinue supplying power to the battery and the battery to supply power to the load to cause the partial discharge of the battery based on the signal.

At step 706, data indicative of a state of health of the battery may be received. For example, the first device (e.g., computing device 104) may receive the data indicative of the state of health of the battery. For example, the state of health may be based on one or more weighted metrics associated with the partial discharge of the battery. The one or more weighted metrics may comprise one or more of a voltage, a first derivative of the voltage, a second derivative of the voltage, a change in voltage from optimal, a change in voltage due to the discharge of the battery, a recovery of the voltage during the discharge of the battery, a first and second derivate of the recovery voltage.

At step 708, an indication to replace the battery may be sent based on the state of health satisfying a threshold. For example, the first device (e.g., computing device 104) may send the indication to replace the battery based on the state of health satisfying the threshold. The state of health may comprise one or more of a percentage of an original capacity of the battery or a remaining life of the battery. For example, the state of health may indicate that the current capacity of the battery is below a threshold percentage of an original capacity (e.g., 20% of the original charging capacity) of the battery or the state of health may indicate that the remaining life of the battery is below a threshold duration (e.g., minutes, hours, days, months, years, remaining charging cycles, etc.). The first device may send the indication to replace the battery based on one or more of the current capacity being below the threshold percentage or the battery has a remaining life below the threshold duration.

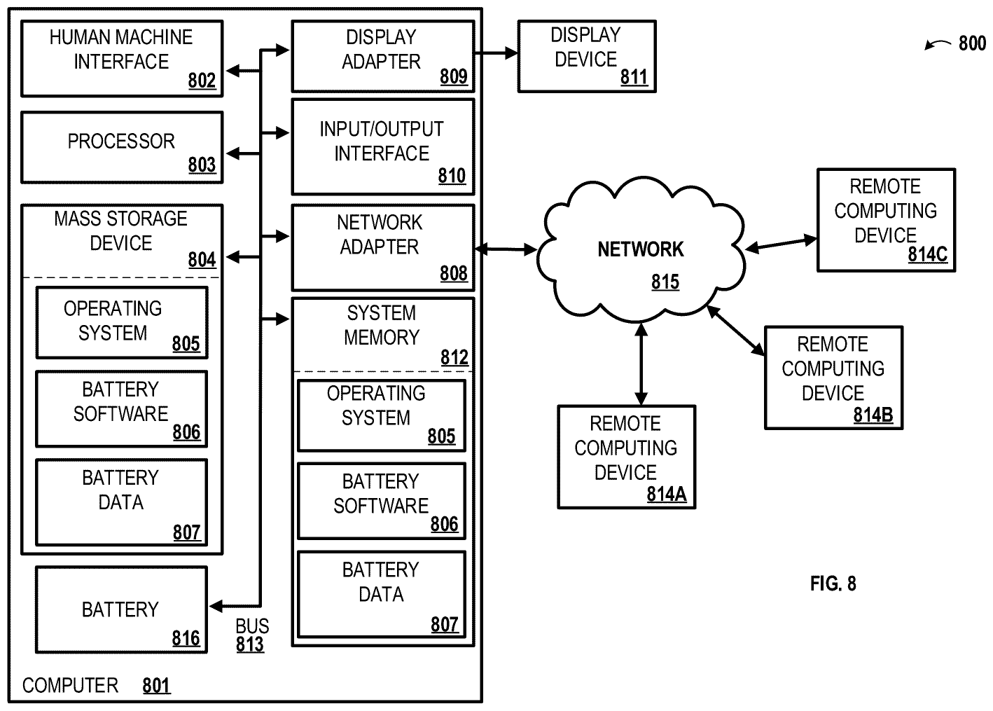

FIG. 8 is a block diagram illustrating an example computing device. The methods and systems can be implemented on a computer 801 as illustrated in FIG. 8 and described below. By way of example, the device 102, and the computing device 104 of FIG. 1 can be a computer 801 as illustrated in FIG. 8. Similarly, the methods and systems disclosed can utilize one or more computers to perform one or more functions in one or more locations. FIG. 8 is a block diagram illustrating an exemplary operating environment 800 for performing the disclosed methods. This exemplary operating environment 800 is only an example of an operating environment and is not intended to suggest any limitation as to the scope of use or functionality of operating environment architecture. Neither should the operating environment 800 be interpreted as having any dependency or requirement relating to any one or combination of components illustrated in the exemplary operating environment 800.

The present methods and systems can be operational with numerous other general purpose or special purpose computing system environments or configurations. Examples of well-known computing systems, environments, and/or configurations that can be suitable for use with the systems and methods comprise, but are not limited to, personal computers, server computers, laptop devices, and multiprocessor systems. Additional examples comprise set top boxes, programmable consumer electronics, network PCs, minicomputers, mainframe computers, distributed computing environments that comprise any of the above systems or devices, and the like.

The processing of the disclosed methods and systems can be performed by software components. The disclosed systems and methods can be described in the general context of computer-executable instructions, such as program modules, being executed by one or more computers or other devices. Generally, program modules comprise computer code, routines, programs, objects, components, data structures, and/or the like that perform particular tasks or implement particular abstract data types. The disclosed methods can also be practiced in grid-based and distributed computing environments where tasks are performed by remote processing devices that are linked through a communications network. In a distributed computing environment, program modules can be located in local and/or remote computer storage media including memory storage devices.

Further, one skilled in the art will appreciate that the systems and methods disclosed herein can be implemented via a general-purpose computing device in the form of a computer 801. The computer 801 can comprise one or more components, such as one or more processors 803, a system memory 812, and a bus 813 that couples various components of the computer 801 including the one or more processors 803 to the system memory 812. In the case of multiple processors 803, the system can utilize parallel computing.

The bus 813 can comprise one or more of several possible types of bus structures, such as a memory bus, memory controller, a peripheral bus, an accelerated graphics port, and a processor or local bus using any of a variety of bus architectures. By way of example, such architectures can comprise an Industry Standard Architecture (ISA) bus, a Micro Channel Architecture (MCA) bus, an Enhanced ISA (EISA) bus, a Video Electronics Standards Association (VESA) local bus, an Accelerated Graphics Port (AGP) bus, and a Peripheral Component Interconnects (PCI), a PCI-Express bus, a Personal Computer Memory Card Industry Association (PCMCIA), Universal Serial Bus (USB) and the like. The bus 813, and all buses specified in this description can also be implemented over a wired or wireless network connection and one or more of the components of the computer 801, such as the one or more processors 803, a mass storage device 804, an operating system 805, battery software 806, battery data 807, a network adapter 808, system memory 812, an Input/Output Interface 810, a display adapter 809, a display device 811, a battery 816, and a human machine interface 802, can be contained within one or more remote computing devices 814A-814C at physically separate locations, connected through buses of this form, in effect implementing a fully distributed system.

The computer 801 typically comprises a variety of computer readable media. Exemplary readable media can be any available media that is accessible by the computer 801 and comprises, for example and not meant to be limiting, both volatile and non-volatile media, removable and non-removable media. The system memory 812 can comprise computer readable media in the form of volatile memory, such as random access memory (RAM), and/or non-volatile memory, such as read only memory (ROM). The system memory 812 typically can comprise data such as battery data 807 and/or program modules such as operating system 805 and battery software 806 that are accessible to and/or are operated on by the one or more processors 803.

The computer 801 can also comprise other removable/non-removable, volatile/non-volatile computer storage media. By way of example, the computer 801 can comprise a mass storage device 804 which can offer non-volatile storage of computer code, computer readable instructions, data structures, program modules, and other data for the computer 801. For example, a mass storage device 804 can be a hard disk, a removable magnetic disk, a removable optical disk, magnetic cassettes or other magnetic storage devices, flash memory cards, CD-ROM, digital versatile disks (DVD) or other optical storage, random access memories (RAM), read only memories (ROM), electrically erasable programmable read-only memory (EEPROM), and the like.

Optionally, any number of program modules can be stored on the mass storage device 904, including by way of example, an operating system 805 and battery software 806. One or more of the operating system 805 and battery software 806 (or some combination thereof) can comprise elements of the programming and the battery software 806. Battery data 807 can also be stored on the mass storage device 804. Battery data 807 can be stored in any of one or more databases known in the art. Examples of such databases comprise, DB2®, Microsoft® Access, Microsoft® SQL Server, Oracle®, mySQL, PostgreSQL, and the like. The databases can be centralized or distributed across multiple locations within the network 815.

The user can enter commands and information into the computer 801 via an input device (not shown). Examples of such input devices comprise, but are not limited to, a keyboard, pointing device (e.g., a computer mouse, remote control), a microphone, a joystick, a scanner, tactile input devices such as gloves, and other body coverings, motion sensor, and the like These and other input devices can be connected to the one or more processors 803 via a human machine interface 802 that is coupled to the bus 813, but can be connected by other interface and bus structures, such as a parallel port, game port, an IEEE 1394 Port (also known as a Firewire port), a serial port, network adapter 808, and/or a universal serial bus (USB).

A display device 811 can also be connected to the bus 813 via an interface, such as a display adapter 809. It is contemplated that the computer 801 can have more than one display adapter 809 and the computer 801 can have more than one display device 811. For example, a display device 811 can be a monitor, an LCD (Liquid Crystal Display), light emitting diode (LED) display, television, smart lens, smart glass, and/or a projector. In addition to the display device 811, other output peripheral devices can comprise components such as speakers (not shown) and a printer (not shown) which can be connected to the computer 801 via Input/Output Interface 810. Any step and/or result of the methods can be output in any form to an output device. Such output can be any form of visual representation, including, but not limited to, textual, graphical, animation, audio, tactile, and the like. The display 811 and computer 801 can be part of one device, or separate devices.

The battery 816 may comprise any type of battery. For example, the battery 816 may comprise a rechargeable battery. The battery 816 may comprise any size, model, and/or type of battery. For example, the battery 816 may comprise a cylindrical battery (e.g., AAA, C, D, CR2, 2CR5, etc.), a rectangular battery (9 volt, 12 volt, etc.), a button cell battery (e.g., CR927, CR1220, CR2025, etc.), a zinc air cell battery (e.g., AC10, ZA13, A312, etc.), and so forth. The battery 816 may be made of any material such as alkaline, carbon zinc, Lithium-ion (Li-ion), Nickel Cadmium (Ni—Cd), Nickel-Metal Hydride (Ni-MH), Lithium-Manganese Dioxide (LiMnO₂), or any suitable battery. In an example, the battery 816 may comprise a plurality of batteries. For example, the plurality of batteries may be configured in one or more strings of the same batteries in series, parallel, or both series and parallel. The battery 816 may have a storage capacity, which is the total amount of power (e.g., charge) that the battery 816 can store.

The computer 801 can operate in a networked environment using logical connections to one or more remote computing devices 814A, 814B, and 814C. By way of example, a remote computing device 814A-814C can be a personal computer, a computing station (e.g., a workstation), a portable computer (e.g., a laptop, a mobile phone, a tablet device), a smart device (e.g., a smartphone, a smart watch, an activity tracker, a smart apparel, a smart accessory), a security and/or monitoring device, a server, a router, a network computer, a peer device, an edge device or other common network node, and so on. Logical connections between the computer 801 and a remote computing device 814A-814C can be made via a network 815, such as a local area network (LAN) and/or a general wide area network (WAN). Such network connections can be through a network adapter 808. A network adapter 808 can be implemented in both wired and wireless environments. Such networking environments are conventional and commonplace in dwellings, offices, enterprise-wide computer networks, intranets, and the Internet.

For purposes of illustration, application programs and other executable program components such as the operating system 805 are illustrated herein as discrete blocks, although it is recognized that such programs and components can reside at various times in different storage components of the computer 801, and are executed by the one or more processors 803 of the computer 801. An implementation of battery software 806 can be stored on or transmitted across some form of computer readable media. Any of the disclosed methods can be performed by computer readable instructions embodied on computer readable media. Computer readable media can be any available media that can be accessed by a computer. By way of example and not meant to be limiting, computer readable media can comprise “computer storage media” and “communications media.” “Computer storage media” can comprise volatile and non-volatile, removable and non-removable media implemented in any methods or technology for storage of information such as computer readable instructions, data structures, program modules, or other data. Exemplary computer storage media can comprise RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by a computer.

The methods and systems can employ artificial intelligence (AI) techniques such as machine learning and iterative learning. Examples of such techniques include, but are not limited to, expert systems, case based reasoning, Bayesian networks, behavior based AI, neural networks, fuzzy systems, evolutionary computation (e.g., a genetic algorithms), swarm intelligence (e.g., an ant algorithms), and hybrid intelligent systems (e.g., expert inference rules generated through a neural network or production rules from statistical learning).

While the methods and systems have been described in connection with preferred embodiments and specific examples, it is not intended that the scope be limited to the particular embodiments set forth, as the embodiments herein are intended in all respects to be illustrative rather than restrictive.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

It will be apparent to those skilled in the art that various modifications and variations can be made without departing from the scope or spirit. Other embodiments will be apparent to those skilled in the art from consideration of the specification and practice disclosed herein. It is intended that the specification and examples be considered as exemplary only, with a true scope and spirit being indicated by the following claims.

1. A method comprising:
receiving, by a device, a signal to initiate a test of a battery configured to supply back-up power to a load associated with the device, wherein the battery is receiving primary power to maintain a first charge level of the battery;
based on the signal, causing the primary power to discontinue supplying power to the battery and the battery to supply power to the load to cause a partial discharge of the battery from the first charge level to a second charge level of the battery;
determining one or more weighted metrics of the battery during the partial discharge of the battery; and
sending, based on the one or more weighted metrics, an indication of a state of health of the battery.

2. The method of claim 1, wherein causing the partial discharge of the battery from the first charge level to the second charge level comprises causing the battery to discharge for a time period or causing the battery to discharge an amount of electric charge from the battery.

3. The method of claim 1, further comprising, causing, based on the discharge of the battery from the first charge level to the second charge level, the battery to discontinue supplying power to the load and the primary power to resume supplying power to the battery.

4. The method of claim 1, wherein determining the one or more weighted metrics of the battery during the partial discharge of the battery comprises:
determining one or more metrics of the battery during the partial discharge of the battery; and
assigning a weight to each metric of the one or more metrics.

5. The method of claim 4, wherein assigning a weight to each metric of the one or more metrics comprises assigning, based on an application of a machine learning model to the one or more metrics, a weight to each metric of the one or more metrics.

6. The method of claim 1, wherein determining the one or more weighted metrics of the battery during the partial discharge of the battery comprises determining the one or more weighted metrics at one or more depth of discharge levels during the partial discharge of the battery.

7. The method of claim 1, wherein determining the one or more weighted metrics of the battery comprises determining, based on one or more characteristics of the battery, the one or more weighted metrics of a plurality of weighted metrics.

8. The method of claim 7, wherein the one or more characteristics of the battery comprise one or more of a battery model of the battery or a battery type of the battery, and wherein the plurality of weighted metrics comprise one or more of a voltage, a first derivative of the voltage, a second derivative of the voltage, a change in voltage from optimal, a change in voltage due to the discharge of the battery, a recovery of the voltage during the discharge of the battery, a first and second derivate of the recovery voltage.

9. The method of claim 1, wherein the state of health comprises one or more of a percentage of an original capacity of the battery or a remaining life of the battery.

10. A method comprising:
receiving, by a device, a signal to initiate a test of a battery configured to supply back-up power to a load associated with the device, wherein the battery is receiving primary power to maintain a charge level of the battery;
based on the signal, causing the primary power to discontinue supplying power to the battery and the battery to supply power to the load to cause a discharge of the battery to a threshold percentage of the charge level of the battery;
causing, based on the discharge of the battery to the threshold percentage, the battery to discontinue discharging;
determining a first weighted metric and a second weighted metric associated with the discharge of the battery; and
sending, based on a comparison of the first weighted metric and the second weighted metric, an indication of a state of health of the battery.

11. The method of claim 10, wherein causing the discharge of the battery to the threshold percentage comprises causing the discharge of the battery for a time period or causing a discharge of an amount of electric charge from the battery.

12. The method of claim 10, wherein causing the battery to discontinue discharging comprises causing the battery to discontinue supplying power to the load and the primary power to resume supplying power to the battery.

13. The method of claim 10, wherein one or more of the first weighted metric or the second weighted metric comprises one or more of a voltage, a first derivative of the voltage, a second derivative of the voltage, a change in voltage from optimal, a change in voltage due to the discharge of the battery, a recovery of the voltage during the discharge of the battery, a first and second derivate of the recovery voltage.

14. The method of claim 10, wherein determining the first weighted metric and the second weighted metric associated with the discharge of the battery comprises:
determining a first metric and a second metric associated with the discharge of the battery; and
assigning a first weight to the first metric and a second weight to the second metric.

15. The method of claim 14, wherein assigning the first weight to the first metric and the second weight to the second metric comprises assigning, based on one or more characteristics of the battery, the first weight to the first metric and the second weight to the second metric.

16. The method of claim 15, wherein the one or more characteristics of the battery comprises one or more of a battery model of the battery or a battery type of the battery.

17. The method of claim 10, wherein the state of health comprises one or more of a percentage of an original capacity of the battery or a remaining life of the battery.

18. A method comprising:
sending, by a first device to a second device, a signal to initiate a test of a battery configured to supply back-up power to a load associated with the second device, wherein the battery is receiving primary power to maintain a charge level of the battery;
causing, based on the signal, the primary power to discontinue supplying power to the battery and the battery to supply power to the load to cause a partial discharge of the battery;
receiving data indicative of a state of health of the battery, wherein the state of health is based on one or more weighted metrics associated with the partial discharge of the battery; and
sending, based on the state of health satisfying a threshold, an indication to replace the battery.

19. The method of claim 18, wherein the one or more weighted metrics comprise one or more of a voltage, a first derivative of the voltage, a second derivative of the voltage, a change in voltage from optimal, a change in voltage due to the discharge of the battery, a recovery of the voltage during the discharge of the battery, a first and second derivate of the recovery voltage.

20. The method of claim 18, wherein the state of health comprises one or more of a percentage of an original capacity of the battery or a remaining life of the battery.
